(19) United States
(12) Patent Application Publication
(10) Pub. No.: US 2011/0278601 A1
(43) Pub. Date: Nov. 17, 2011

(54) LIGHT EMITTING DIODE PACKAGE

(75) Inventors: MIN-TSUN HSIEH, Hukou (TW); WEN-LIANG TSENG, Hukou, (TW); LUNG-HSIN CHEN, Hukou (TW); CHIH-YUNG LIN, Hukou (TW)

(73) Assignee: ADVANCED OPTOELECTRONIC TECHNOLOGY, INC., Hsinchu Hsien (TW)

(21) Appl. No.: 12/979,368

(22) Filed: Dec. 28, 2010

(30) Foreign Application Priority Data
May 14, 2010 (CN) 201010169688.8

(51) Int. Cl. H01L 33/48

(52) U.S. Cl. 257/88; 257/E33.056; 257/E33.059

(57) ABSTRACT

An LED package includes a silicon base, an LED and a glass encapsulant. The silicon base has a first surface and a second surface opposite to the first surface. The LED chip is located on the first surface of the silicon base. The glass encapsulant covers the LED chip. The glass encapsulant and the silicon base define a receiving space therebetween to receive the LED chip. The glass encapsulant is fixedly engaged with the first surface of the silicon base, so the glass encapsulant and the silicon base enclose the LED chip.

### TECHNICAL FIELD

The invention generally relates to a photoelectric device, and more particularly to a light-emitting diode (LED) package.

### BACKGROUND

Related light sources, such as high-pressure mercury lamps, metal halide lamps, and xenon lamps are commonly used in commercial products. However, there are problems associated with these lamp technologies including poor luminous efficacy, high power requirement, cooling challenges, short lifetime, high cost and use of mercury, a known environmental hazard. Light emitting diodes provide improved lifetime, lower power consumption, smaller size, and no mercury. Thus, LEDs are popularly replacing the related light sources in some products, such as scanners, backlight units, dashboard lights and illumination devices.

LED packages usually include epoxy resin, polyphthalamide (PPA) or polymethyl methacrylate (PMMA) as encapsulants, formed through injection molding, transfer molding or casting. Epoxy resin provides good hardness, rigidity and transparency. However, light with lower wavelengths causes epoxy resin to qualitatively change or discolor, typically becoming yellow. This will impart a yellow cast to the light, thereby lowering the effective color temperature and the luminous efficacy of the device.

Therefore, it is desirable to provide an LED package, which can overcome the described limitations.

### BRIEF DESCRIPTION OF THE DRAWINGS

Many aspects of the LED packages can be better understood with reference to the following drawings. The components in the drawings are not necessarily drawn to scale, emphasis instead being placed upon clearly illustrating the principles of the present invention. Moreover, in the drawings, like reference numerals designate corresponding parts throughout the several views.

FIG. 1 is a top view of an LED package according to a first embodiment;

FIG. 2 is a cross section of the LED package along the cross line II-II of FIG. 1;

FIG. 3 is a cross section of the LED package along the cross line III-III of FIG. 1;

FIG. 4 through FIG. 8 are cross sections showing various locations of fluorescent material in the encapsulant applied to the LED package of FIG. 1;

FIG. 9 is a cross section of an encapsulant according to a second embodiment;

FIG. 10 is a schematic, isometric view of an encapsulant according to a third embodiment;

FIG. 11 is a schematic, isometric view of an encapsulant according to a fourth embodiment;

FIG. 12 is a cross section of the encapsulant along the cross line XII-XII of FIG. 11;

FIG. 13 is a cross section of an LED package according to a fifth embodiment;

FIG. 14 is a top view of an LED package according to a sixth embodiment;

FIG. 15 is a cross section of the LED package along the cross line XV-XV of FIG. 14;

FIG. 16 through FIG. 19 are cross sections showing various locations of fluorescent material in the encapsulant applied to the LED package of FIG. 14;

FIG. 20 is a cross section of an encapsulant according to a seventh embodiment;

FIG. 21 is an exploded view of an LED package according to an eighth embodiment; and

FIG. 22 is an exploded view of an LED package according to a ninth embodiment.

Corresponding reference characters indicate corresponding parts throughout the drawing. The exemplifications set out herein illustrate at least one preferred embodiment of the present invention, in one form, and such exemplifications are not to be construed as limiting the scope of the invention in any manner.

### DETAILED DESCRIPTION OF PREFERRED EMBODIMENTS

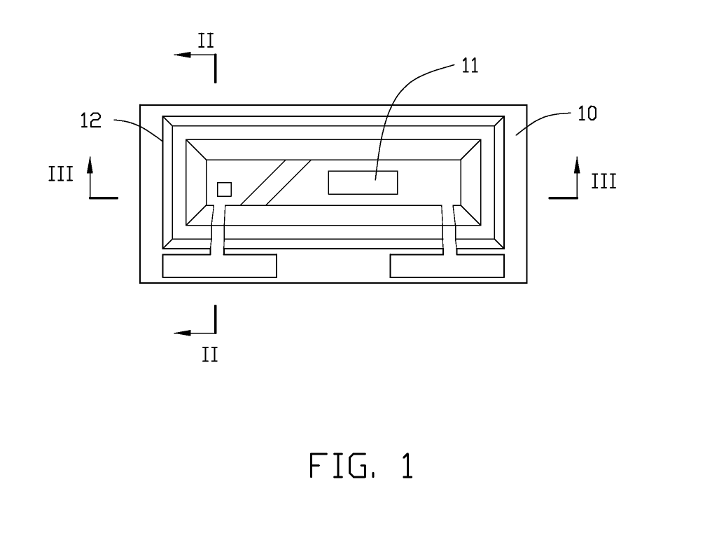

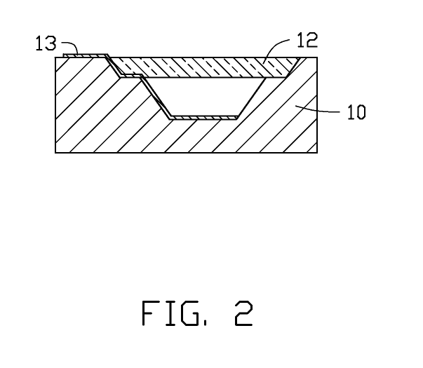

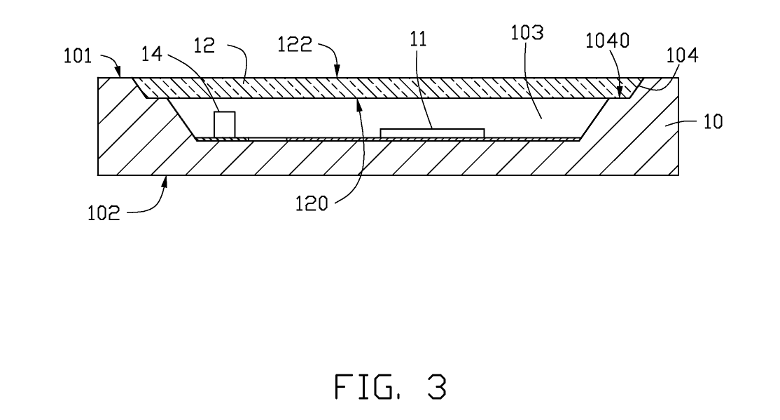

As shown in FIG. 1 through FIG. 3, the LED package includes a base 10, an LED chip 11 mounted on the base 10, an encapsulant 12 covering the LED chip 11, two leading wires 13 located on a surface of the base 10, and a zener diode 14 mounted on the base 10. The encapsulant 12 is made of glass.

The base 10 is a silicon base including silicon or silicide. The base 10 has a first surface 101 and a second surface 102 opposite to the first surface 101. The first surface 101 defines a first recess 104 to support the glass encapsulant 12 and a second recess 103 located at the bottom of the first recess 104 to support the LED chip 11 and the zener diode 14.

Both the first recess 104 and the second recess 103 are rectangular in top view, trapezoidal in cross section, and have a flat bottom surface. The cross sections of both the first recess 104 and the second recess 103 increase in size from bottom to top. Thus, both the first recess 104 and the second recess 103 have angled side surfaces.

The second recess 103 is smaller than the first recess 104 in top view, so the first recess 104 and the second recess 103 define a step portion. The step portion can hold the glass encapsulant 12 in the first recess 104, and receive the LED chip 11 and the zener diode 14 in the second recess 103 under the first recess 104.

The LED chip 11 is located in the second recess 103 and mounted on the bottom surface of the second recess 103. The zener diode 14 may also be located on the second recess 103 and electrically connected to the LED chip 11. The zener diode 14 stabilizes working voltage of the LED package, so the LED chip 11 is protected from unstable current. The LED chip 11 may be any kind of LED. Since the materials of the base 10 and the glass encapsulant 12 of the present disclosure are stable in short wavelength light, the LED chip 11 with short wavelength can be adopted, such as a wavelength range from 330 nanometers (nm) to 450 nm.

The leading wires 13 are electrically connected to the LED chip 11, providing contact pads thereto. The leading wires 13 may extend from the first surface 101 to the second surface 102 in other embodiment. In such a case, the LED package may be a surface mounted device (SMD). The leading wires 13 may be indium tin oxide (ITO), copper (Cu), nickel (Ni), titanium (Ti), silver (Ag), aluminum (Al), tin (Sn), gold (Au) or any alloy thereof, and may be formed by plating, sputtering, evaporation deposition or electronic beam. The LED chip 11 and the zener diode 14 may be electrically connected to leading wires 13 by wire bonding or flip chip bonding, but are not limited thereto.

The glass encapsulant 12 may fill the first recess 104. The glass encapsulant 12 and the base 10 define a receiving space therebetween to receive the LED chip 11. The glass encapsulant 12 is fixedly engaged with the bottom surface 1040 of the first recess 104, so the glass encapsulant 12 and the base 10 enclose the LED chip 11. Thus, the bottom of the glass encapsulant 12 may be substantially identical with the first recess 104.

The glass encapsulant 12 has a light-incident surface 120 to receive light from the LED chip 11, and a light-emitting surface 122 from which the light exits. In this embodiment, the glass encapsulant 12 is a flat glass board, and the light-incident surface 120 and the light-emitting surface 122 are both plane surfaces parallel and opposite to each other.

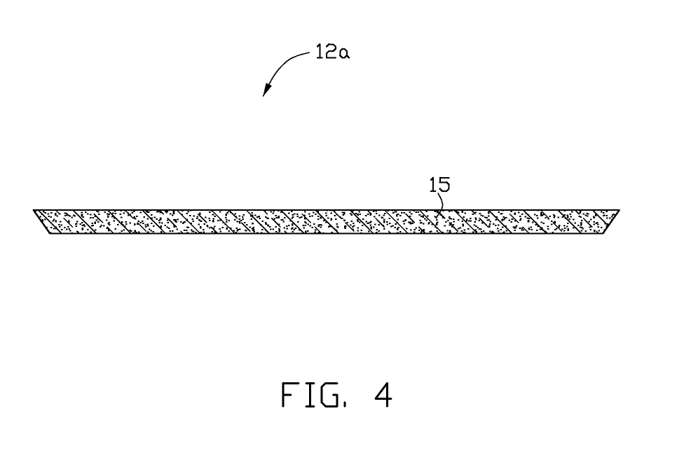

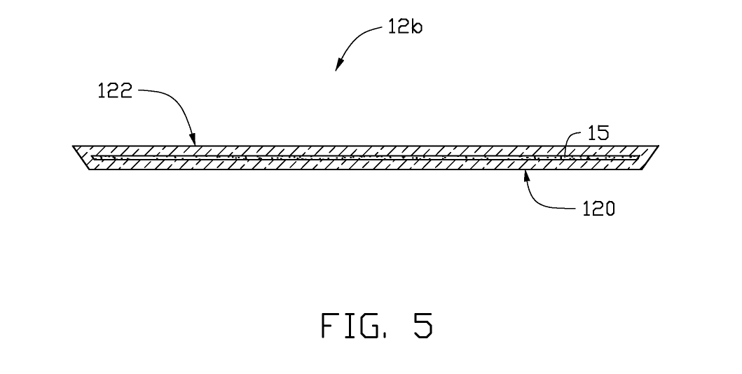

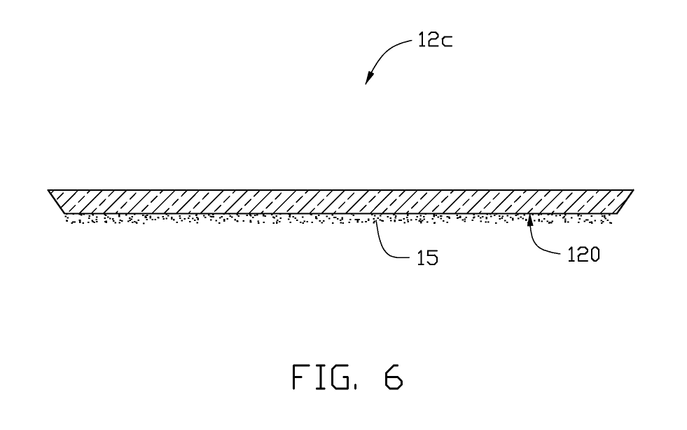

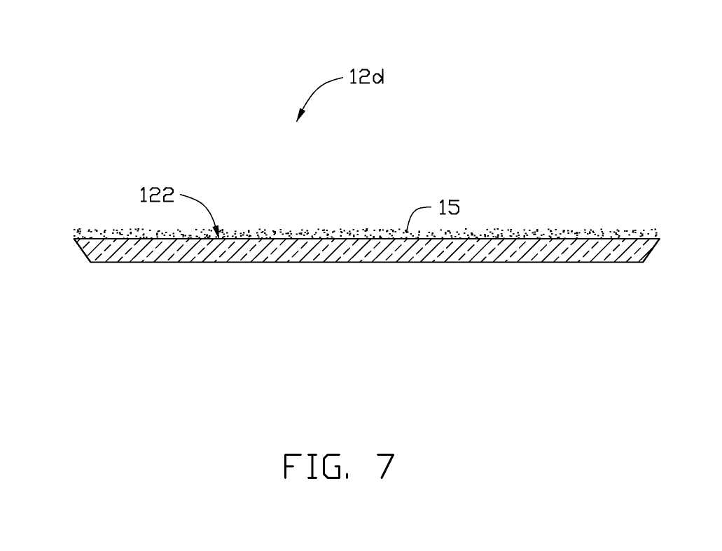

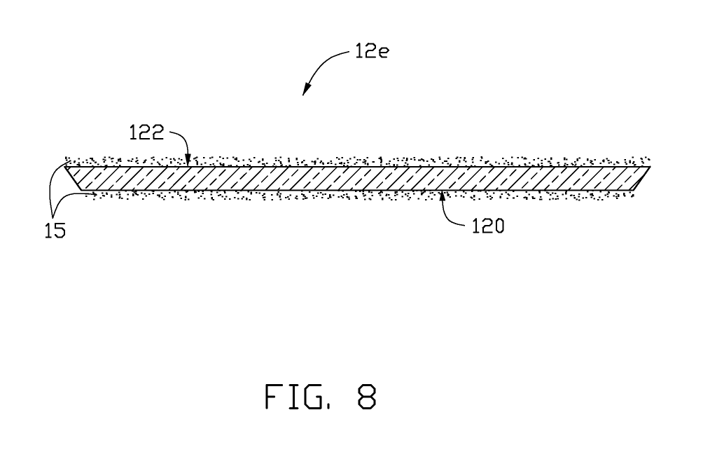

The LED package includes fluorescent material 15 to adjust the illumination. FIG. 4 through FIG. 8 illustrate various locations of fluorescent material 15 in the encapsulant 12, which may be applied to the LED package of FIG. 1. In FIG. 4, the fluorescent material 15 is uniformly doped in the glass encapsulant 12a. In FIG. 5, the fluorescent material 15 is a film sandwiched in the glass encapsulant 12b, between the light-incident surface 120 and the light-emitting surface 122, so light radiated from the LED chip 11 passes the light-incident surface 120, the fluorescent material 15 and the light-emitting surface 122 in order. In FIG. 6, the light-incident surface 120 of the glass encapsulant 12c is coated with the fluorescent material 15. In FIG. 7, the light-emitting surface 122 of the glass encapsulant 12d is coated with the fluorescent material 15. In FIG. 8, both the light-incident surface 120 and the light-emitting surface 122 of the glass encapsulant 12e are coated with the fluorescent material 15. In other embodiments, the LED chip 11 may be directly coated with the fluorescent material 15. The fluorescent material 15 may include at least one of garnet, sulfide, phosphate, nitride, oxynitride, silicate, arsenide, selenide, telluride or any mixture thereof.

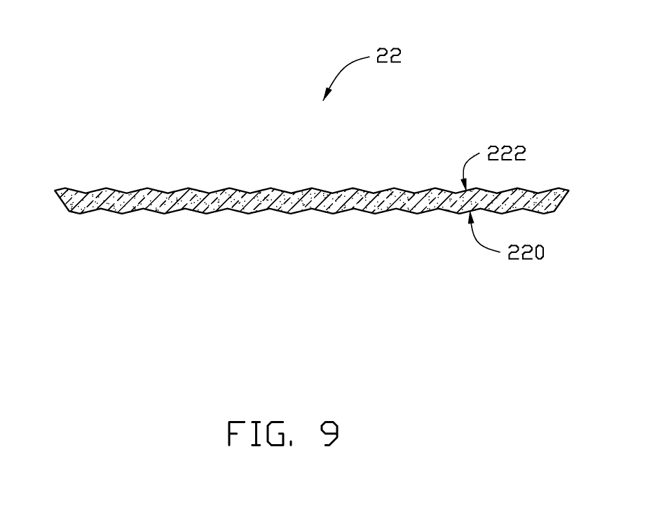

The glass encapsulant may have various shapes in other embodiments. As shown in FIG. 9, a second embodiment differs from the first embodiment only in that the glass encapsulant 22 is a wave-like board. The light-incident surface 220 and the light-emitting surface 222 are both wave-like surfaces, which change the direction of light vertically entering the glass encapsulant 22.

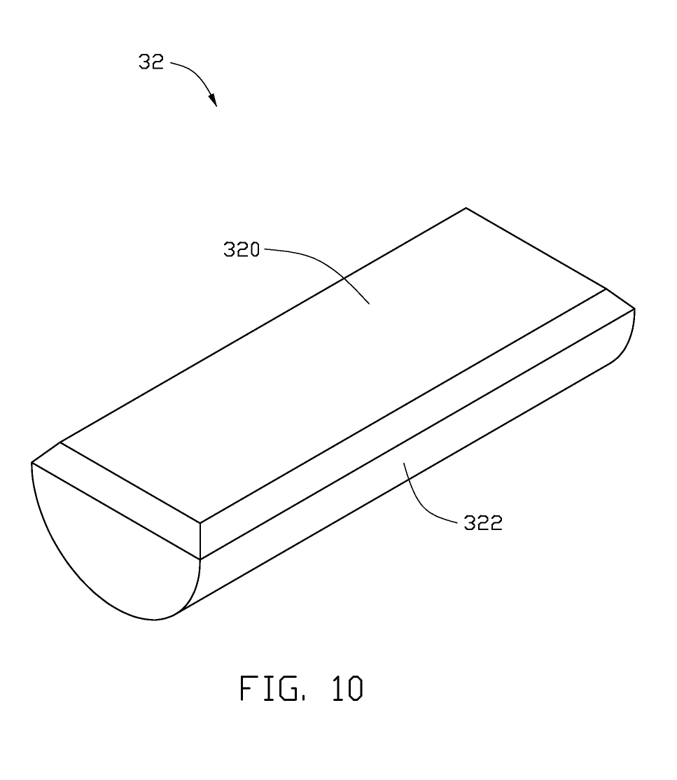

As shown in FIG. 10, a third embodiment differs from the first embodiment only in that the glass encapsulant 32 is curved. The glass encapsulant 32 is substantially semi-cylindrical, and more specially includes a trapezoid cube matching the first recess 104, and a semi-cylinder extending from one side of the trapezoid cube for emitting the light. Thus, the glass encapsulant 32 is held by cooperation of the trapezoid cube portion and the first recess 104, and the illumination distribution of the LED package is adjusted by the semi-cylindrical portion. A flat surface of the trapezoid cube adjacent the LED chip 11 is the light-incident surface 320 of the glass encapsulant 32, and the convex surface of the semi-cylinder opposite to the trapezoid cube is the light-emitting surface 322. In this embodiment, the two opposite semi-circular planes at two ends of the semi-cylinder may also be portions of the light-emitting surface 322. It is noted that the trapezoid cube portion is contoured to match the first recess 104 of the base 10, and its shape is not limited by the drawings. In other embodiments, the shape of first recess 104 of the base 10 and the trapezoid cube portion of the glass encapsulant 42 may be a cylinder, an elliptic cylinder or any column.

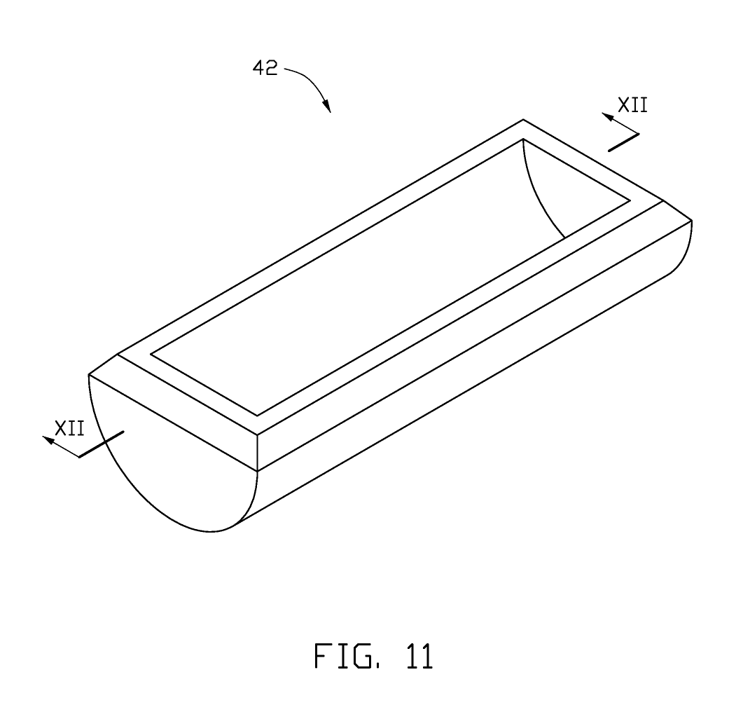

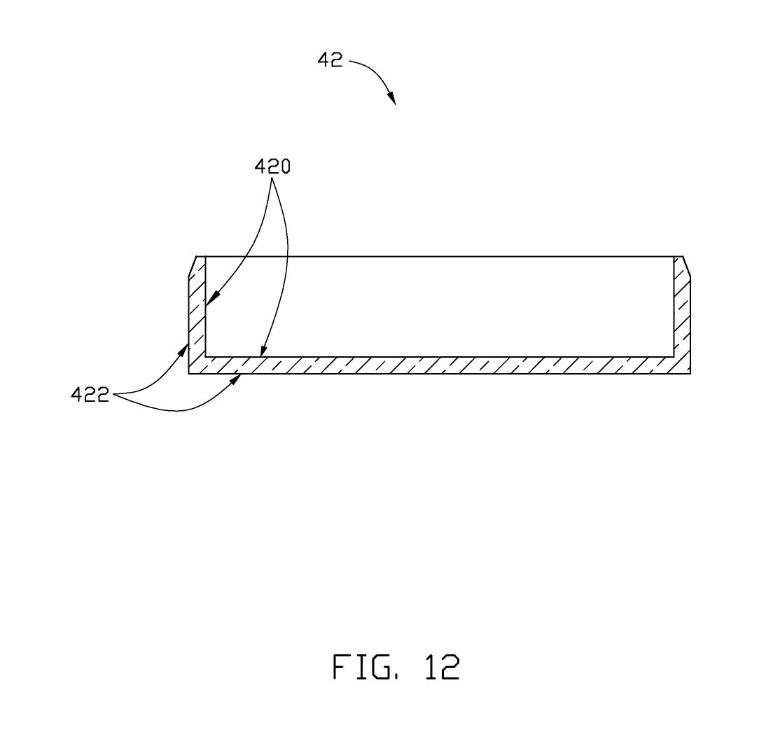

As shown in FIG. 11 and FIG. 12, a fourth embodiment differs from the third embodiment only in that the glass encapsulant 42 is hollow. The hollow opening of the glass encapsulant 42 may face the LED chip 11. Thus, the light-incident surface 420 of the glass encapsulant 42 includes five planes to define a recess. The light-emitting surface 422 includes the convex surface and the two opposite semi-circular planes of the semi-cylinder.

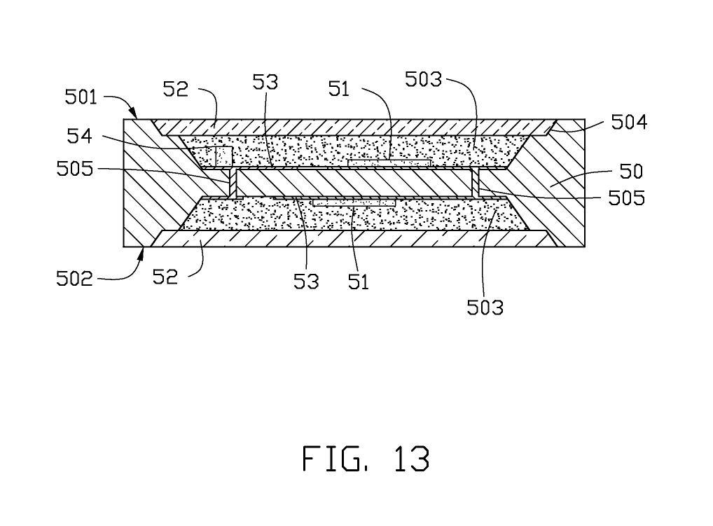

As shown in FIG. 13, a fifth embodiment differs from the first embodiment in that while the second surface 502 of the base 50 is similar to the first surface 101 of the base 10 to receive one more LED chip 51, the base 50 further defines two through holes 505 in the fifth embodiment. The LED package includes a base 50 having four recesses on two opposite surfaces, two LED chips 51 mounted on the opposite surfaces of the base 50, two encapsulants 52 respectively covering the two LED chips 51, two leading wires 53 electrically connected the two LED chips 51, and a zener diode 54 mounted on the base 50.

The first surface 501 and the second surface 502 are substantially symmetrical to each other, with the two LED chips 51 respectively mounted thereon. The second surface 502 also defines a first recess 504 to support one glass encapsulant 52 and a second recess 503 located at the bottom of the first recess 504 to support one LED chip 51. Each through hole 505 communicates the two second recesses 503 of the first surface 501 and the second surface 502, and the two leading wires 53 respectively extend from the first surface 501 toward the second surface 502 through the through holes 505. The portions of the leading wires 53 filling in the through holes 505 may be any conductor, such as copper or silver.

The various glass encapsulants shown in FIG. 4 through FIG. 11 can also be adopted in the LED package of the fifth embodiment.

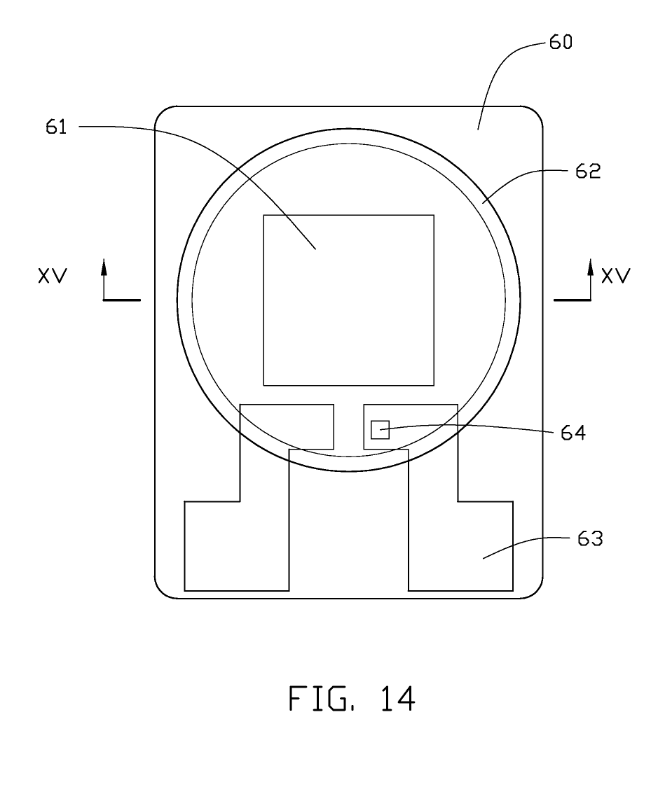

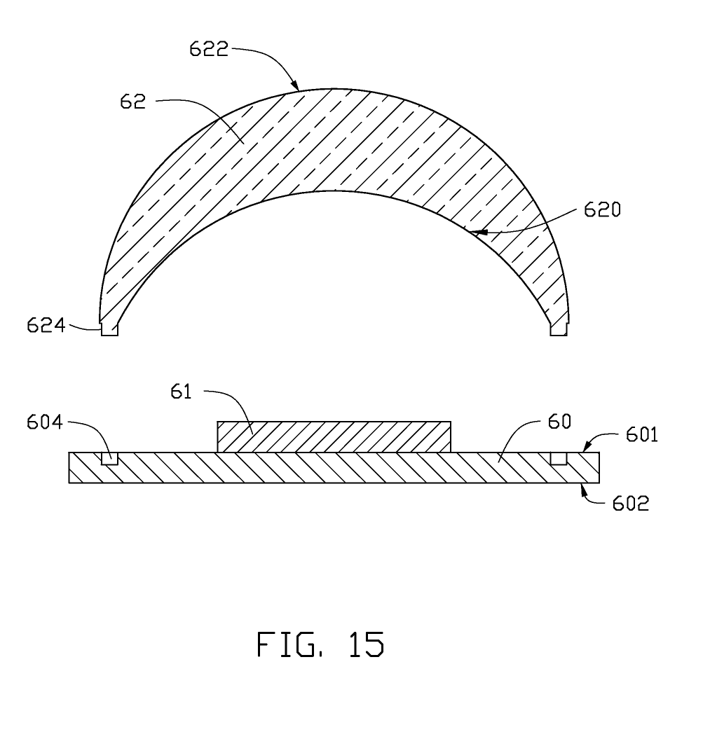

As shown in FIG. 14 and FIG. 15, a sixth embodiment differs from the first embodiment only in that the base 60 and the encapsulant 62 are combined by mortise and tenon, and the mortise and the tenon have a circle shape.

The glass encapsulant 62 is a hollow hemisphere, and the hollow opening faces the base 60 to receive the LED chip 61. The glass encapsulant 62 defines a ring tenon 624 to join the base 60. In this embodiment, the thickness of the glass encapsulant 62 is gradually decreased from center to edge. Since the brightness of the LED chip 61 is usually decreased from center to edge, such a thickness of the glass encapsulant 62 can effectively improve the light uniformity of the LED package.

The first surface 601 of the base 60 defines a ring mortise 604 surrounding the LED chip 61. The size and shape of the ring mortise 604 are substantially identical to the size and shape of the ring tenon 624, so the glass encapsulant 62 can be fixed on the base 60. The size and shape of the ring mortise 604 and the ring tenon 624 are not limited to the drawings, and can be any proper structures.

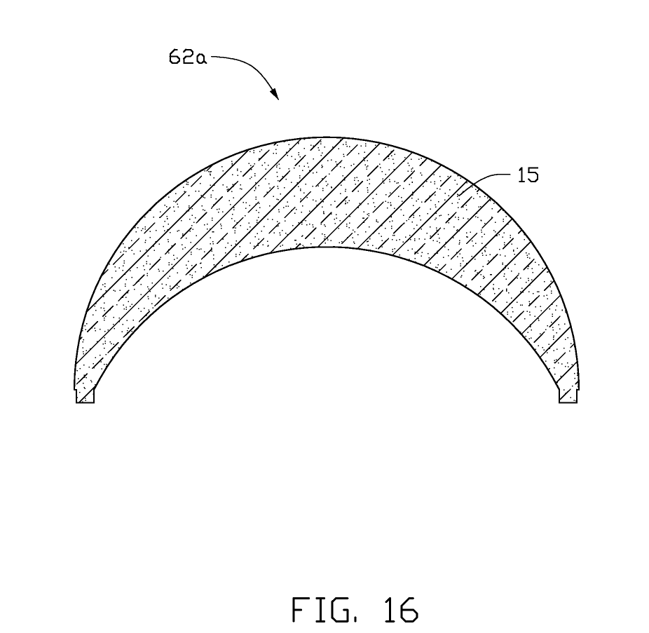

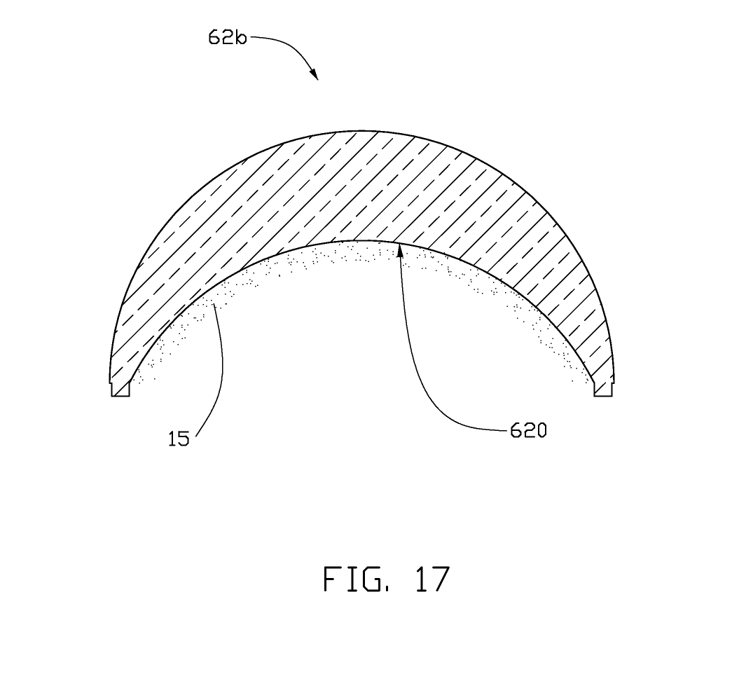

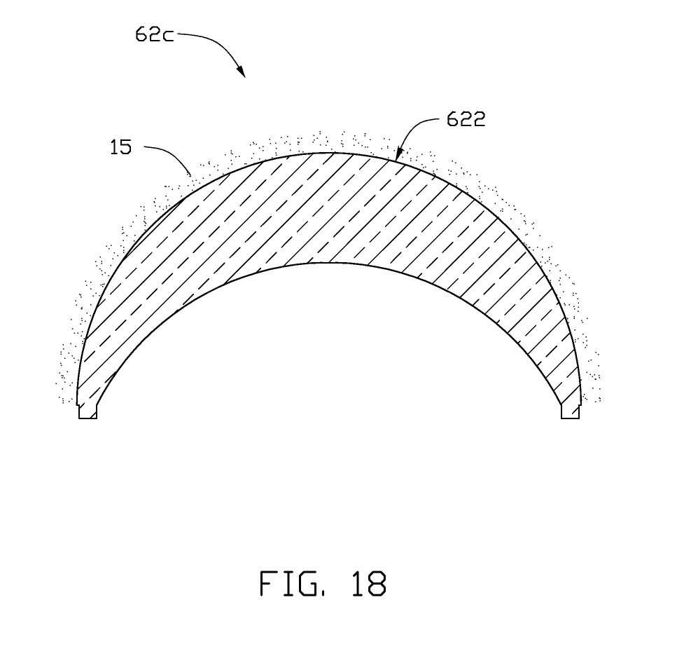

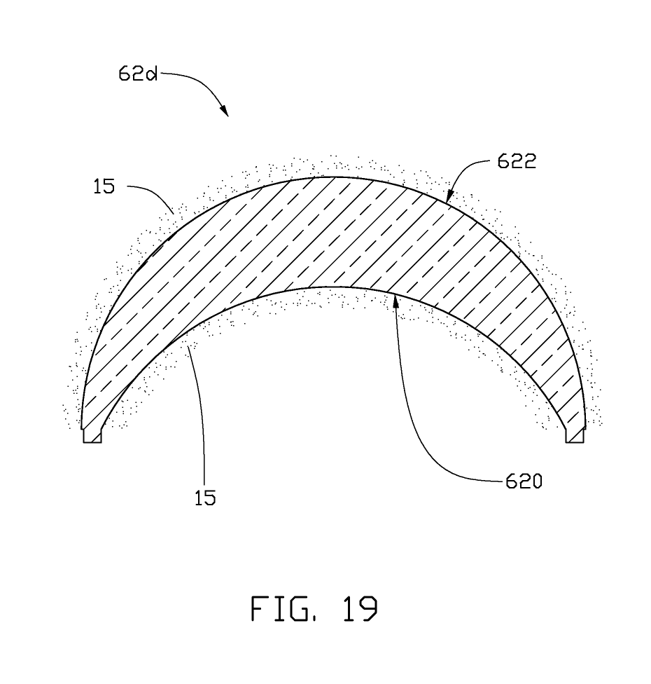

Various encapsulants applied to the LED package of FIG. 14 are shown in FIG. 16 through FIG. 19. In FIG. 16, fluorescent material 15 is uniformly doped in the glass encapsulant 62a. In FIG. 17, the light-incident surface 620 of the glass encapsulant 62b is coated with the fluorescent material 15. In FIG. 18, the light-emitting surface 622 of the glass encapsulant 62c is coated with the fluorescent material 15. In FIG. 19, both the light-incident surface 620 and the light-emitting surface 622 of the glass encapsulant 62d are coated with the fluorescent material 15.

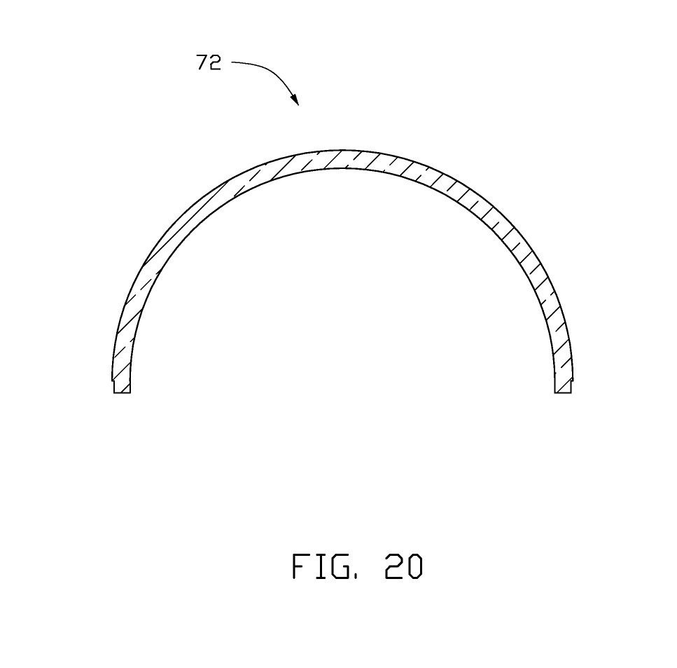

In FIG. 20, the thickness of the glass encapsulant 72 is uniform from center to edge. In such a case, light emitted toward different directions passes the glass encapsulant 72 of the same thickness. Thus, tinges of color in the center and in the periphery are uniform, tinges of color in different parts are uniform, and lunar halo effect can be avoided.

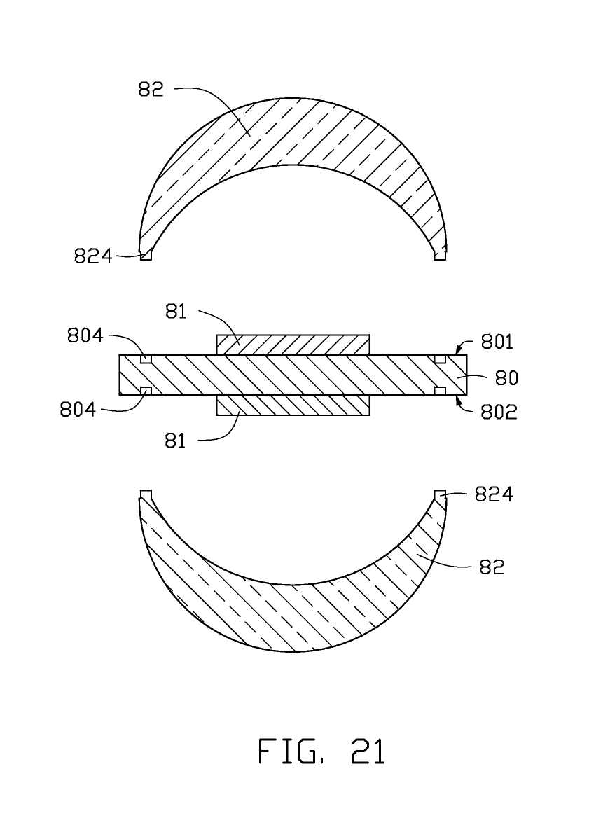

As shown in FIG. 21, an eighth embodiment differs from the sixth embodiment only in that the second surface 802 of the base 80 receives one more LED chip 81. The base 80 defines two ring mortises 804 respectively surrounding the two LED chips 81 on the first surface 801 and the second surface 802. The LED package includes two glass encapsulants 82. Each glass encapsulant 82 defines a ring tenon 824 engaged with the corresponding ring mortise 804. Thus, the two glass encapsulants 82 are respectively fixed on the first surface 801 and the second surface 802 of the base 80.

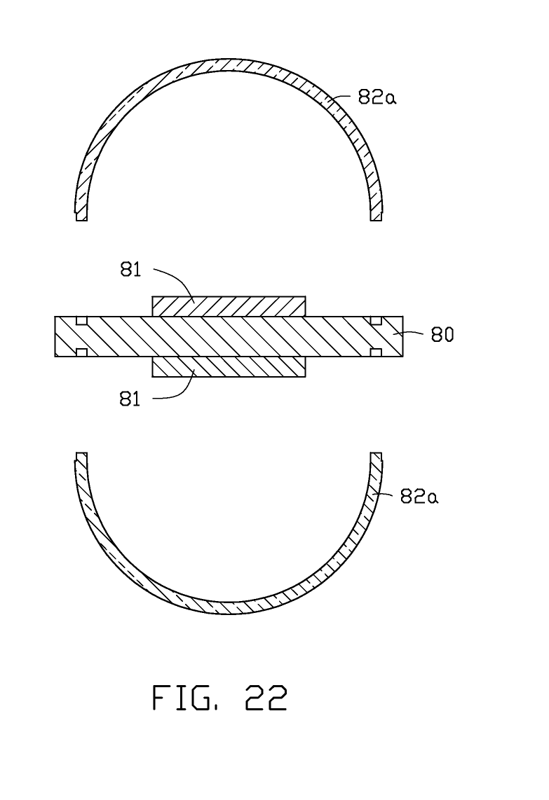

As shown in FIG. 22, a ninth embodiment differs from the eighth embodiment only in that the thickness of each glass encapsulant 82a is uniform from center to edge.

A method of forming the LED package of the present disclosure includes etching the first and second surfaces to form one or more recesses or mortises; mounting one or more the LED chips on the base; placing one or more glass encapsulants above the LED chips; and placing gel at the junction between the glass encapsulant and the base by a dispensing process. The dispensing process can be performed before and/or after the glass encapsulants are placed on the base.

The glass encapsulants of the present disclosure are received in and securely held by the base. Accordingly, the glass encapsulant can separate from the LED chip, and is protected from the heat generated by the LED chip. Since the glass encapsulant is made of glass, light with shorter wavelengths does not cause the glass to qualitatively change or discolor, and the yellow cast is avoid. Thus, the LED package is suitable for high-power LEDs and short wavelength LEDs, such as other ultraviolet (UV) light LED or near UV light LED. Moreover, the LED package of the present disclosure is suitable to work in surrounding having shorter wavelength light. If the LED package includes two LED chips on opposite surfaces, the LED packages are suitable to be electrically connected in series or in parallel, so the applications of the LED packages are more versatile. The various positions of the fluorescent material can prevent UV leakage from the LED package.

It is believed that the present embodiment and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An LED package, comprising:
a silicon base comprising a first surface and a second surface opposite to the first surface;
a first LED chip located on the first surface of the silicon base; and
a first glass encapsulant covering the first LED chip, wherein the first glass encapsulant and the silicon base define a receiving space therebetween to receive the first LED chip, the first glass encapsulant is fixedly engaged with the first surface of the silicon base, and the first glass encapsulant and the silicon base enclose the first LED chip.

2. The LED package of claim 1, further comprising a zener diode located on the first surface and electrically connected to the first LED chip.

3. The LED package of claim 1, wherein the first surface defines a first recess to support the first glass encapsulant and a second recess located at a bottom of the first recess to support the first LED chip.

4. The LED package of claim 3, wherein the second recess is smaller than the first recess, and the first recess and the second recess define a step portion.

5. The LED package of claim 3, wherein the first glass encapsulant fills the first recess and engages with the step portion.

6. The LED package of claim 1, wherein the first glass encapsulant comprises a light-incident surface and a light-emitting surface.

7. The LED package of claim 6, wherein the first glass encapsulant is selected from a group consisting of a flat board, a spherical convex, an elliptical convex and a spherical shell.

8. The LED package of claim 6, wherein the light-emitting surface of the first glass encapsulant is selected from a group consisting of a plane surface, a wave-like surface and a convex surface.

9. The LED package of claim 3, further comprising:
a second LED chip located on the second surface of the silicon base; and
a second glass encapsulant covering the second LED chip, wherein the second glass encapsulant is fixedly engaged with the second surface of the silicon base, and the second glass encapsulant and the silicon base enclose the first LED chip.

10. The LED package of claim 9, wherein the second surface defines a third recess to support the second glass encapsulant and a fourth recess located at a bottom of the third recess to support the second LED chip.

11. The LED package of claim 10, wherein the silicon base further defines a through hole to communicate the second recess and the fourth recess.

12. The LED package of claim 10, further comprising a leading wire extending from the first surface to the second surface through the through hole, the leading wire electrically connecting with the first and second LED chips.

13. The LED package of claim 1, wherein the first surface defines a first ring mortise surrounding the first LED chip, and the first glass encapsulant defines a first ring tenon to joint the first ring mortise of the silicon base.

14. The LED package of claim 13, wherein the light-incident surface and the light-emitting surface of the first glass encapsulant are respectively a concave surface and a convex surface.

15. The LED package of claim 13, wherein a thickness of the first glass encapsulant is gradually decreased from center to edge.

16. The LED package of claim 13, wherein a thickness of the first glass encapsulant is uniform from center to edge.

17. The LED package of claim 1, further comprising fluorescent material on the first glass encapsulant.

18. The LED package of claim 13, further comprising:
a second LED chip located on the second surface of the silicon base; and
a second glass encapsulant covering the second LED chip, wherein the second glass encapsulant is fixedly engaged with the second surface of the silicon base, and the second glass encapsulant and the silicon base enclose the first LED chip.

19. The LED package of claim 18, wherein the second surface defines a second ring mortise surrounding the second LED chip, and the second glass encapsulant defines a second ring tenon to joint with the second ring mortise of the silicon base.

20. The LED package of claim 1, wherein the first LED chip and the first glass encapsulant define a gap therebetween.
